(19) United States
(12) Patent Application Publication
(10) Pub. No.: US 2015/0102817 A1
(43) Pub. Date: Apr. 16, 2015

(54) SHORT-CIRCUIT DETECTION APPARATUS FOR DETECTING SHORT CIRCUITS OF A BATTERY CELL AND METHOD FOR SHORT-CIRCUIT DETECTION

(71) Applicant: Robert Bosch GmbH, Stuttgart (DE)

(72) Inventors: Ralf Angerbauer, Moeglingen (DE); Alexander Reitzle, Neu-Ulm (DE); Joachim Fetzer, Bad-Ditzenbach (DE)

(21) Appl. No.: 14/515,057

(22) Filed: Oct. 15, 2014

(30) Foreign Application Priority Data
Oct. 15, 2013 (DE) 10 2013 220 760.3

(51) Int. Cl. G01R 31/02; H01M 6/50; G01R 31/36

(52) U.S. Cl. CPC G01R 31/025; G01R 31/3606; G01R 31/3658; H01M 6/5083
USPC 324/426

(57) ABSTRACT

A short-circuit detection apparatus for detecting short circuits (20, 30) of a battery cell (1), characterized by a current registering device (10), which is arranged in the interior of the battery cell (1) or between the exterior of the battery cell (1) and an external terminal (4, 5) of the battery cell (1) for the purpose of registering a current through the battery cell (1).

### BACKGROUND OF THE INVENTION

The present invention relates to a short-circuit detection apparatus for detecting short circuits of a battery cell, to a battery cell, to a battery comprising a plurality of battery cells, and to a method for detecting a short circuit.

A lithium-ion battery usually consists of a multiplicity of battery cells. These cells in turn, in a simplified representation, generally consist of a metallic housing, normally an aluminum housing, and two differently polarized electrodes, the cathode and the anode. In order to enable the reversible process between charging and discharging, lithium cations are exchanged between both electrodes.

Since the lithium cations in the respective solid electrodes are transported too slowly for automotive applications, however, the electrodes are backed with thin-walled films in a typical arrangement according to the current prior art, wherein said films are typically produced from aluminum or copper and the same film material is used for anode and cathode. In order to obtain a commensurate power, the two films with anode and cathode material are stacked and wound together in a plurality of layers to form a composite, the so-called “jelly roll”. A microporous, thin-walled separator membrane between the electrode layers provides for spatial separation and electrical isolation of these two differently polarized masses. A battery cell typically comprises one or more jelly rolls.

Lithium-ion cells can heat up to a very great extent in the event of electrical overloading, e.g. owing to overcharging, mechanical overloading, for instance as a result of damage to the cell housing, as a result of unintended short circuits, e.g. as a result of contact between voltage-carrying parts of a cell and metallic objects. This causes the insulating films of the cell winding to melt. A cell-internal short circuit ensues with possibly explosive evolution of pressure within one or more cells. This can entail serious consequences.

An important aspect relevant to safety in the assembly of batteries composed of a plurality of individual cells is the use of small parts, such as e.g. shims and the like. Such small parts are used, inter alia, to ensure a secure connection between the cells. At the same time, however, these individual parts also constitute a hazard potential. If they reach critical locations in the battery, for instance between oppositely charged parts of individual cells or, for example, in the case of a series circuit of a plurality of cells, between locations carrying voltage relative to one another within such a battery, e.g. as a result of loss or as a result of slipping during an assembly process, there is a great risk of a short circuit. Particularly in the event of contact between the terminal of a battery cell and its oppositely polarized housing, an external short circuit can be generated, which in the worst case can lead to explosion of the entire battery.

An external short circuit can likewise occur in the event of insulation faults between cell and cooling plate, if an electrical connection is produced as a result of a conductive connection of the cooling plate and a terminal of a cell. Such hazards arise during maintenance and repair work. Particularly during production, an external short circuit can occur as a result of a double insulation fault, for example between different electrodes and the cooling plate, said external short circuit jeopardizing the function and safety of the entire battery.

### SUMMARY OF THE INVENTION

In order to solve the problem described above and thus to reduce or to eliminate the risk of a short circuit, the invention proposes a short-circuit detection apparatus which can register short circuits of a battery cell. Said short-circuit detection apparatus comprises a current registering device for registering a current through the battery cell, wherein the current registering device is arranged in the interior of the battery cell or between the exterior of the battery cell and an external terminal of the battery cell. A short circuit, as described with reference to the prior art, can be an internal or an external short circuit. Both types of short circuits cause a considerable current rise in the current-carrying parts of the battery cell.

In the case of an internal short circuit, the separating layer between the electrodes is perforated and fails, such that electrons from one electrode to the other electrode do not have to flow via the intended external current circuit of the cell from one electrode to the other, but rather cross directly from one electrode to the other at the short-circuit location. This leads to an abrupt discharge of the electrode sections at the short-circuit location. The virtually resistanceless connection of the two electrodes is limited only by the resistance of the conductors and of the electron sources. The flowing current typically attains its maximum value. The electrode sections away from the location of the short circuit thus also reduce their potential in a short time by virtue of the fact that a movement of the charge carriers takes place there. In this case, the conductive structures supply electrons that flow to the short-circuit location, or take up electrons therefrom. An intensive transfer of lithium cations between the electrodes takes place at the same time. As a result of the intensive transfer of lithium and the presence of free electrons at the short-circuit location, at the latter metallic lithium can additionally deposit at the anode. This cathode material then becomes the oxidizing element and loses its stability, such that further internal short circuits arise or the existing short circuit expands. As a result of the subsequent supply of electrons away from the short-circuit location, high currents flow in the conductive electron transport structures on account of the internal short circuit, said currents initially having comparatively steep rising edges. The current gradients resulting therefrom lead to magnetic fields having appreciable field strengths. Consequently, a current registering device that registers such a magnetic field, for example, can be arranged at a suitable location at such current-carrying conductive structures. As a result of the internal short circuit, the externally available voltage collapses, moreover, such that current flowing in the direction of the external electrical circuit of the cell abruptly becomes lower. This, too, can be registered by a suitably positioned current registering device. External short circuits that can occur while an external electrical circuit is connected to the battery cell, or if such an electrical circuit has not yet been connected, for instance during the production of a battery, also lead to a suddenly greatly changing current flow in the electron-conducting structures of the battery cell that are present in the interior or else between the interior of the battery cell and external battery terminals. An arrangement of the current registering device at these electron-conducting structures mentioned is therefore expedient and suitable. A current registering device can be in particular a sensor, in particular a sensor that can register a magnetic field generated by the short-circuit current. Such a sensor can be part of a current measuring device, further components of which can be arranged elsewhere at the battery cell or outside the latter. One advantage of the arrangement of a current registering device at the locations mentioned is that internal and/or external short circuits are measurable at one location by means of only a single current registering device. Moreover, short circuits are measurable even if an external terminal is not yet connected to an external electrical circuit. Particularly during the production of battery cells and batteries produced therefrom, this is highly advantageous since typical current and voltage measuring devices for the operation of a battery cell or battery are arranged outside the battery cell or battery and/or cannot yet be mounted or connected to the battery cell.

In one embodiment, a short-circuit detection apparatus is proposed which additionally comprises an ascertaining device, which processes a current signal from the current registering device and identifies therefrom whether a current rise is present which can be used to deduce a short circuit of the battery cell. In particular, the gradient of a measured current profile can be determined and the latter can be compared with one or a plurality of threshold values. It is conceivable to distinguish between internal and external short circuits with a plurality of threshold values, wherein the threshold value for an internal short circuit can be greater than that for an external short circuit, particularly if the current registering device is arranged in the interior of the battery cell. The ascertaining device can operate in an analog or digital fashion and correspondingly receive analog or digital signals or data from a current registering device or an interposed current measuring device.

In a further embodiment of the short-circuit detection apparatus, the current registering device is arranged such that it can register current through a metallic current collector of the battery cell. The current collector is typically arranged in the interior of the battery cell and conducts current from one of the electrodes to one of the external terminals of the battery cell. Large portions of the current collectors of a battery cell are arranged in the interior thereof. Such a current collector is embodied in particular at least partly as a metallic film, typically as a thin-walled film, on which electrode material is arranged. Electrons from the electrode material thus cross into the metallic film and are conducted as current, under certain circumstances via other parts of the current collector, to the external terminals of the battery. The current registering device can be arranged at the anode or the cathode; it is also conceivable to arrange a respective current registering device at the anode and at the cathode. Alternatively, it is also conceivable to arrange a current registering device outside the actual battery cell which comprises the electrodes, at a feed to an external terminal of the battery. While a measurement in the interior of the battery cell has advantages for registering internal short circuits, the measurement between the actual battery cell and an external terminal of the battery cell has the advantage that here higher currents flow in the case of an external short circuit, which are registerable better. An internally arranged current registering device has the advantage over the current registering devices arranged in the feed line to the external terminal that the short-circuit current of an external short circuit likewise flows via the internal current registering device, while the currents of an internal short circuit flow outside the battery cell to a lesser extent. The risk of an external short circuit arises particularly if the housing of the battery cell is polarized. As has already been described with reference to the prior art, in particular small parts used for connecting the battery cell to further elements can cause a hazard as a result of falling and the formation of a short circuit between locations having different potentials. Such elements may be, for example, a polarized housing, a polarized cooling sheet or an external terminal. The polarization may be undesired and thus defective, which entails a high risk on account of the serious consequences of a short circuit.

In a further embodiment of the short-circuit detection apparatus, the current registering device is embodied as a current sensor that can register a magnetic field of the short-circuit current. In this case, by way of example, a coil can serve as a pick-up for changes in the magnetic field. Alternatively, a Hall sensor or a directly mapping current sensor can be used. With these, a magnetic field generated by the current is directly registerable in each case. Particularly with a Hall probe, a DC current is registerable, while changes in the magnetic field, in particular, are registerable with typical coils. It is furthermore conceivable for the current registering device to be embodied as a compensation current converter with a soft-magnetic probe or with a Hall probe. The current registering device can also be a current sensor with which a current-proportional voltage is registerable, for instance by means of a shunt resistor. In the event of a short circuit arising, there is a very great rise in the magnetic field strength and thus, particularly in current registering devices which operate with a coil, high induced voltages. The latter are a measure of the current gradient occurring or a current rise, with the result that such a voltage can be compared directly or after amplification with a threshold value in order to arrive at the detection of a short circuit. Signals from other sensors can be conditioned suitably.

In a further embodiment of the short-circuit detection apparatus, the latter can initiate a reaction measure if a short circuit has been detected. In particular, the ascertaining device can output a command or a signal for initiating a reaction measure. By way of example, a current reduction or a current interruption is appropriate as a reaction measure. For this purpose, in particular, the battery cell can be disconnected from the external terminal or the external terminal can be disconnected from loads or other peripheral elements, preferably by a corresponding switch or a safety device being opened, such that a current flow is no longer possible. In order to reduce the current, an additional resistor can be connected into an electrical circuit. Furthermore, it is conceivable for the battery cell to be discharged in a targeted manner via a resistor connected, in particular, between the two electrodes. In this case, preferably, a considerable portion of the energy of the battery cell is converted into heat in the resistor. Furthermore, it is conceivable to bind lithium in an electrolyte of the battery cell. In this way, the ion exchange between the electrodes is reduced or prevented, such that further discharge is no longer possible. A conceivable explosion of the cell can thus be prevented at best. Furthermore, it is conceivable to carry out a degradation of the insulating layer, typically embodied as a separator film, in which the insulating layer preferably loses its permeability to lithium cations. In this way, likewise, a discharge of the battery is no longer possible, with the result that a short circuit has only little effect after this measure. The initiation of a reaction measure can take place, in particular, if the ascertaining device has ascertained that a short circuit is present.

A further aspect of the invention proposes a battery cell comprising a short-circuit detection apparatus according to any of the embodiments described above.

A further aspect of the invention proposes a battery comprising a plurality of battery cells, at least one of which is equipped with a short-circuit detection apparatus according to any of the embodiments described above. Preferably, all the battery cells in the battery are provided with such a short-circuit detection apparatus. The battery cells can be interconnected in a parallel and/or series circuit in the battery.

Yet another aspect of the invention proposes a method for detecting a short circuit of a battery cell. For this purpose, a signal or data is or are registered by a current registering device arranged in the interior or between the exterior of the battery cell and an external terminal of the battery cell. In this way it is possible to register an increased current and/or a fast current rise in a battery cell, even if the latter is not connected to external loads or systems. By means of such a current and/or current rise it is possible to determine whether a short circuit has occurred. As already described with reference to the short-circuit detection apparatus, such a short circuit can occur in the interior of the battery cell or outside the latter.

One embodiment of the method proposes transmitting a current signal of the current registering device to an ascertaining device, possibly via a current measuring device that suitably conditions the signal from the current registering device. The ascertaining device performs automatic registering of a current or/and of a current rise, wherein the ascertaining device ascertains whether a current magnitude or/and a current rise is/are the consequence of a short circuit. Particularly if a short circuit has been ascertained, a reaction measure to the short circuit can be initiated, preferably by the ascertaining device.

One embodiment of the method proposes, as reaction measure, reducing or interrupting the current through the battery cell. Furthermore, the battery cell could be discharged in a targeted manner with the aid of a resistor connected between two poles of the battery cell, in order to lower the risk of an explosion or fire. Furthermore, it is conceivable to bind lithium in an electrolyte of the battery cell, such that lithium ions cannot act further as charge transfer medium between anode and cathode. Finally, it is furthermore conceivable to bring about a degradation of an insulating layer at the electrode, such that this is no longer permeable to the charge-transferring lithium cations and, consequently, the battery cell can no longer supply current. The consequences of a short circuit can thus be considerably alleviated.

### BRIEF DESCRIPTION OF THE DRAWINGS

Exemplary embodiments of the invention are described in detail below with reference to the accompanying drawings. In the drawings:

FIG. 1 shows a view of a battery cell of one embodiment of the invention,

FIG. 2 shows a cross section through the battery cell from FIG. 1,

FIG. 3 shows the same cross section through the battery cell as in FIG. 2 with an internal short circuit,

FIG. 4 shows the same cross section as in FIG. 3 additionally with current flows arising as a result of the short circuit in the battery cell, and

FIG. 5 shows the same cross section as in FIG. 2 with a schematic illustration of an external short circuit.

### DETAILED DESCRIPTION

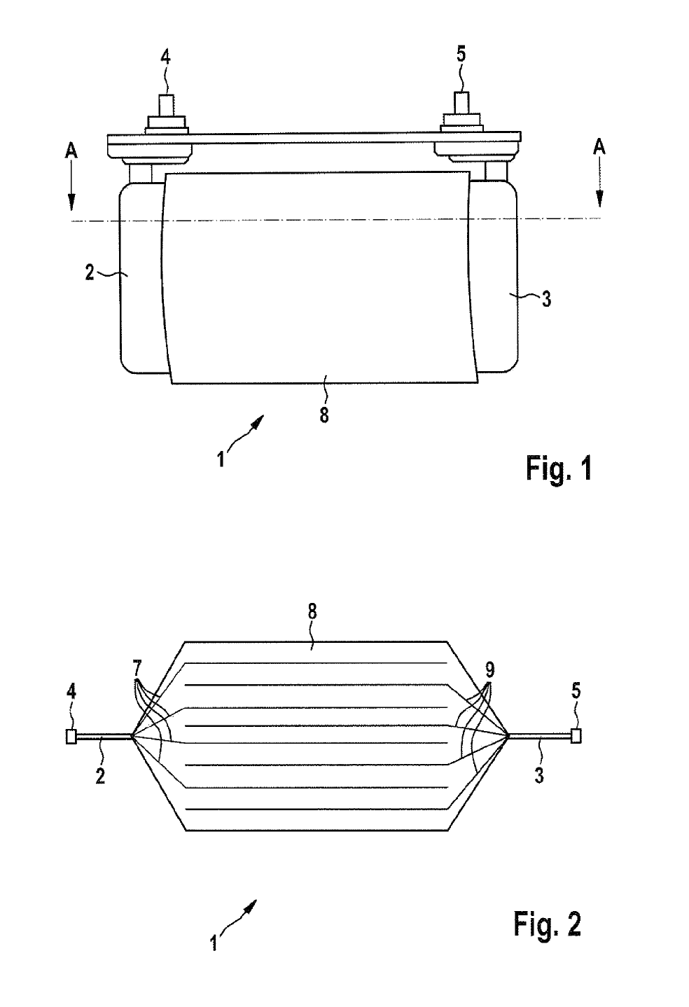

FIG. 1 schematically shows a view of a battery cell 1 embodied as a jelly roll. The battery cell 1 has external terminals 4 and 5 having different polarities. The external terminals 4 and 5 are respectively electrically connected to collectors 2 and 3 for the two electrodes of the battery cell 1. In this case, the collectors 2 and 3 project from a central part of the battery cell 1, wherein the central part comprises the electrode materials and a separator 8. In the variant shown, the separator 8 is embodied as a film (not explicitly illustrated), separates the electrodes from one another and forms an outer surface of the battery cell 1. The dash-dotted line shows a cross-sectional plane, the corresponding cross section of which is illustrated in FIG. 2. The viewing direction in the cross-sectional plane is indicated by the arrows designated by A.

FIG. 2 schematically shows a cross section through a battery cell 1. The battery cell 1 has in its interior two collector films 7 and 9, which take up electric current output by the electrodes and feed it to the collectors 2 and 3. At the collectors 2 and 3, lateral sections of the collector films 7 and 9, respectively, are connected to one another. By virtue of the fact that the battery cell 1 is embodied as a jelly roll, the collector films 7 and 9, illustrated as individual layers, overall are associated with one another electrically and mechanically in the winding direction as well. The collector films 7 and 9 can be led out from the battery cell 1 and combined mechanically to form the collectors 2 and 3.

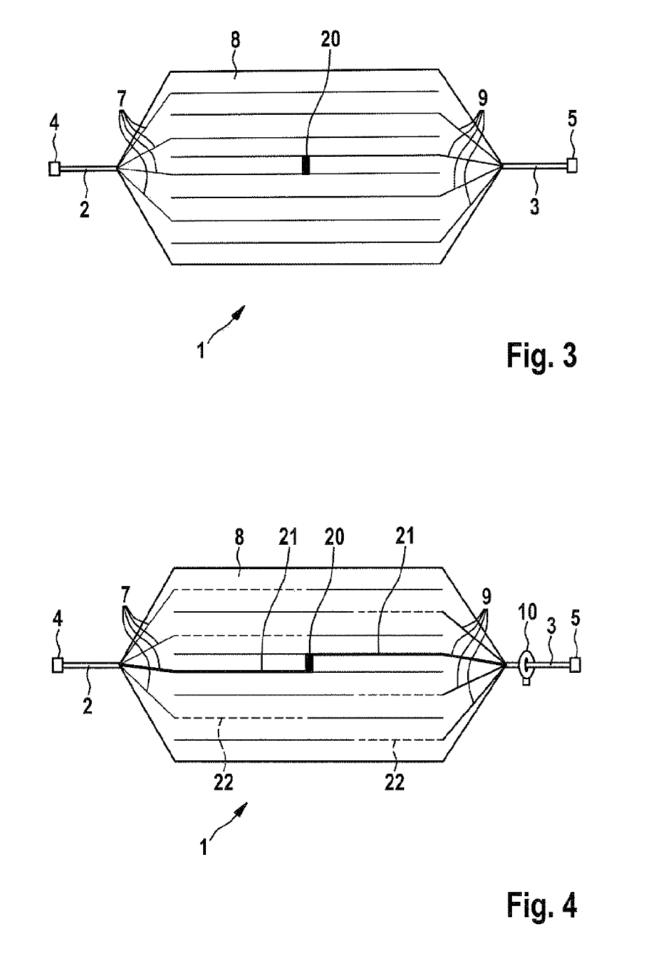

FIG. 3 shows the formation of an internal short circuit 20 in the battery cell 1 in the same cross section as in FIG. 2. The internal short circuit 20 connects a location of the collector film 7 to a location of the collector film 9, the separator film 8 being perforated at this location. The internal short circuit 20 thus allows electrons to cross between the collector films 7 and 9 at the short-circuit location. Normally, the current does not flow via the short-circuit location, but rather is provided at the collectors 2 and 3 for external use. However, the mechanism of supplying the current remains the same, such that the electrodes of the battery cell 1 supply the short-circuit location 20 with current.

FIG. 4 shows the provision of short-circuit current for the internal short circuit 20 in the same cross section as in FIG. 3. Since the battery cell 1 supplies current for the short-circuit location as in normal operation, said current comes from the electrode material and is conducted via the collector films 7 and 9 to the short-circuit location. In this case, electrode material arranged directly around the short-circuit location can conduct the current to the short-circuit location via the sections of the collector films 7 and 9 which are in direct proximity to the short-circuit location 20. However, some locations of the collector films 7 and 9 are connected to the short-circuit location via a current path of extremely low resistance that runs via the combination of the collector films 7 and 9 to a collector 2 and 3, respectively. The corresponding currents 22 in the collector films 7 and 9 are illustrated as dashed lines. At the collectors 2 and 3, these currents are collected and flow across the short-circuit location via a main short-circuit current path 21. The main short-circuit current path 21 then runs in a region of a collector film 7 and respectively 9 which lies in each case in a winding layer in which the short circuit 20 is also situated. In order to detect an internal short circuit 20, a current registering device (not illustrated) can be arranged on a location of one or both collector films 7 and/or 9. The short-circuit current causes a magnetic field that is registered by the current registering device in one variant thereof. The current registering device can be a sensor for measuring DC current. In particular, a registration signal can be derived from the induced magnetic field. By way of example, the current registering device can have a directly mapping current sensor or Hall sensor. However, a measuring pick-up that registers a voltage proportional to the current can likewise be involved, such as e.g. a compensation current converter with Hall probe or a compensation current converter with soft-magnetic probe.

FIG. 4 illustrates a current registering device 10 at or on one of the collectors 3. Particularly if the battery cell 1 is connected to external loads or to further battery cells via its collectors 2 and 3, it is possible to register an internal short circuit 20 by the measurement of the current flow via the collector 2 or 3. For this purpose, a current registering device 10 can be arranged at one of the collectors 2 or 3, in particular wrap around the latter. The internal short circuit 20 usually leads to a voltage dip in the voltage between the collectors 2 and 3. Consequently, a current flow through the collectors 2 and 3 also changes if the battery cell 1 is connected to external electrical components. Furthermore, it is conceivable for the current registering device 10 not to be arranged around all of the ends of the collector film 9 that are combined in the collector 3, but rather only around a portion thereof. Since compensation currents then do not cancel one another out, part of the current flowing internally on account of the short circuit 20 can also be registered by such a current measuring device.

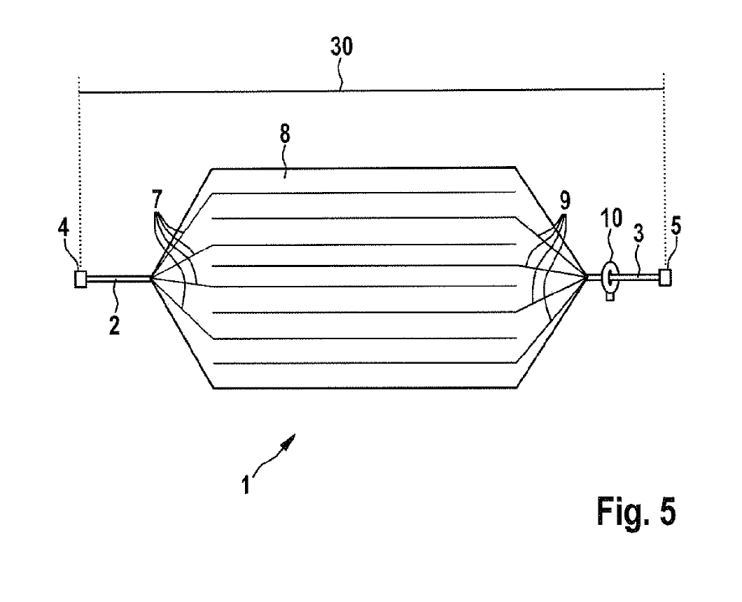

FIG. 5 shows the cross section of the battery cell 1 that is also shown in FIG. 2. In addition, an external short circuit 30 is illustrated schematically. The collector 3 is additionally equipped with a current registering device 10. By means of the current registering device 10 it is possible to identify that an increased current is flowing on account of the external short circuit 30.

As soon as an external electrical short circuit 30 arises, the abrupt discharge of a battery cell occurs, the current of which flows through the short circuit 30. The virtually resistanceless connection is limited only by the internal resistance of the conductors and conduction sources. The flowing current attains its maximum value. The metal films of the affected battery cells 1 will also reduce their potential in a short time away from the main current flow direction, by virtue of the fact that a movement of the charge carriers takes place there. The currents arising in the battery cell 1 on account of external short circuits 30 have comparatively shallow rising edges compared with internal short circuits 20. Nevertheless, their current gradients lead to magnetic fields having field strengths which are distinctly measurable. In the same way as in the measurement of an internal short circuit 20, a current registering device 10 in particular for measuring DC current can be arranged at a collector film 7, 9. The current registering device 10 can pick up an induced magnetic field that arises in the battery cell, for example a directly mapping current sensor or a Hall sensor. A current registering device 10 that registers a voltage proportional to the current can likewise be involved, such as e.g. a compensation current converter with Hall probe or a compensation current converter with soft-magnetic probe. As soon as the measurement variable exceeds a specific limit value, regulating measures are preferably initiated which reduce or prevent the current flow in the damaged battery module. One example of such a measure is, for instance, a targeted discharge of the battery cell 1 with the aid of a resistor. The safety of the battery cell 1 is increased by such measures.

What is claimed is:

1. A short-circuit detection apparatus for detecting short circuits (20, 30) of a battery cell (1), comprising a current registering device (10), which is arranged in the interior of the battery cell (1) or between the exterior of the battery cell (1) and an external terminal (4, 5) of the battery cell (1), for registering a current through the battery cell (1).

2. The short-circuit detection apparatus according to claim 1, further comprising an ascertaining device, to which the current registering device (10) is connected for transmitting a current signal and by means of which a current rise that is registerable by the current registering device (10) owing to a short circuit (20, 30) is ascertainable, wherein a short circuit of the battery cell (1) is detectable on the basis of an increased current and/or current rise.

3. The short-circuit detection apparatus according to claim 1, characterized in that a current through a metallic current collector (7, 9) in the interior of the battery cell (1) is registerable by the current registering device (10), wherein the current collector (7, 9) is configured to feed current from an electrode of the battery cell (1) to an external terminal (4, 5) of the battery cell (1).

4. The short-circuit detection apparatus according to claim 1, characterized in that the current registering device (10) is a current sensor, a Hall sensor or a directly mapping current sensor, by which a magnetic field generated by the current is directly registerable in each case, a current sensor with Hall probe, a compensation current converter with soft-magnetic probe or with Hall probe or a current sensor with registering of current-proportional voltage.

5. The short-circuit detection apparatus according to claim 1, characterized in that with the short-circuit detection apparatus upon detection of a short circuit (20, 30) a reaction measure is initiatable.

6. The short-circuit detection apparatus according to claim 1, characterized in that with the short-circuit detection apparatus upon detection of a short circuit (20, 30) a reaction measure is initiatable by means of the ascertaining device, wherein a current reduction, a current interruption, the binding of lithium in an electrolyte of the battery cell (1), a degradation of an insulating layer (8) between electrodes of the battery cell (1) or a targeted discharge of the battery cell (1) with the aid of a resistor is initiatable as a countermeasure.

7. A battery cell (1), comprising a short-circuit detection apparatus according to claim 1.

8. The battery cell according to claim 7, further comprising an ascertaining device, to which the current registering device (10) is connected for transmitting a current signal and by means of which a current rise that is registerable by the current registering device (10) owing to a short circuit (20, 30) is ascertainable, wherein a short circuit of the battery cell (1) is detectable on the basis of an increased current and/or current rise.

9. The battery cell according to claim 7, characterized in that a current through a metallic current collector (7, 9) in the interior of the battery cell (1) is registerable by the current registering device (10), wherein the current collector (7, 9) is configured to feed current from an electrode of the battery cell (1) to an external terminal (4, 5) of the battery cell (1).

10. The battery cell according to claim 7, characterized in that the current registering device (10) is a current sensor, a Hall sensor or a directly mapping current sensor, by which a magnetic field generated by the current is directly registerable in each case, a current sensor with Hall probe, a compensation current converter with soft-magnetic probe or with Hall probe or a current sensor with registering of current-proportional voltage.

11. The battery cell according to claim 7, characterized in that with the short-circuit detection apparatus upon detection of a short circuit (20, 30) a reaction measure is initiatable.

12. The battery cell according to claim 7, characterized in that with the short-circuit detection apparatus upon detection of a short circuit (20, 30) a reaction measure is initiatable by means of the ascertaining device, wherein a current reduction, a current interruption, the binding of lithium in an electrolyte of the battery cell (1), a degradation of an insulating layer (8) between electrodes of the battery cell (1) or a targeted discharge of the battery cell (1) with the aid of a resistor is initiatable as a countermeasure.

13. A battery comprising a plurality of battery cells, characterized in that at least one battery cell (1) has a short-circuit detection apparatus according to claim 1.

14. A method for detecting a short circuit (20, 30) of a battery cell (1), comprising using a current registering device (10) to register a current through the battery cell (1), wherein the current registering device (10) is arranged in the interior of the battery cell (1) or between the exterior of the battery cell (1) and an external terminal (4, 5) of the battery cell (1).

15. The method according to claim 14, characterized in that a current signal of the current registering device (10) is transmitted to an ascertaining device and the ascertaining device ascertains a current rise owing to a short circuit (20, 30) in order to detect the short circuit (20, 30).

16. The method according to claim 15, characterized in that subsequently a step of implementing a reaction measure to the short circuit (20, 30) is carried out.

17. The method according to claim 16, characterized in that the step of implementing the reaction measure is initiated by the ascertaining device.

18. The method according to claim 16, characterized in that the reaction measure is a current reduction, a current interruption, the binding of lithium in an electrolyte of the battery cell (1), a degradation of an insulating layer (8) of an electrode or a targeted discharge of the battery cell (1) with the aid of a resistor is initiatable as a countermeasure.
